(19) United States
(12) Patent Application Publication
(10) Pub. No.: US 2005/0285247 A1
(43) Pub. Date: Dec. 29, 2005

(54) Substrate-based die package with BGA or BGA-like components

(76) Inventors: Martin Reiss, Dresden (DE); Anton Legen, Muenchen (DE); Manuel Carmona, Barcelona (ES); Steffen Kroehnert, Dresden (DE); Carsten Bender, Dresden (DE)

Correspondence Address: SLATER & MATSIL LLP, 17950 PRESTON ROAD, SUITE 1000, DALLAS, TX, 75252, US

(21) Appl. No.: 11/158,282

(22) Filed: Jun. 21, 2005

(30) Foreign Application Priority Data
Jun. 21, 2004 (DE) 10 2004 029 765.7

(51) Int. Cl. H01L 23/02

(52) U.S. Cl. 257/678

(57) ABSTRACT

A packaged electronic component includes a substrate with an upper layer, a lower layer and a middle layer between the upper layer and the lower layer. The middle layer is formed from a first material that is more flexible than the material of the upper layer and the material of the lower layer. An electronic component, such as a semiconductor chip, can be adhered over the upper layer of the substrate. Solder balls can be adhered over the lower layer of the substrate.

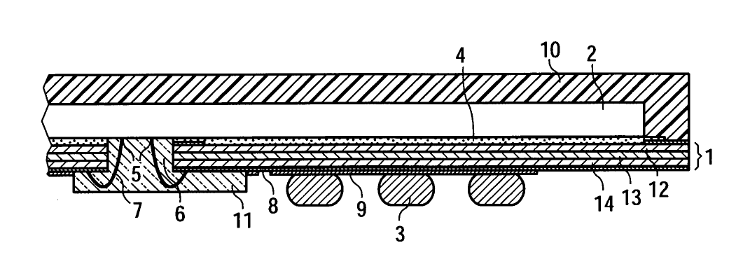

This application claims priority to German Patent Application 10 2004 029 765.7, which was filed Jun. 21, 2004, and is incorporated herein by reference.

### TECHNICAL FIELD

The invention relates generally to component packages and in particular to a substrate-based die package with BGA or BGA-like components.

### BACKGROUND

The encapsulation of a die (semiconductor chip) and bonding channel serves to protect a packaged component and allow for better handling during further processing. For this, the die is surrounded either completely (backside protection) or at least peripherally on its side faces (edge protection) with a molding compound. The encapsulation establishes a firm connection between the molding compound and the die and also between the molding compound and the substrate, so that, apart from the connection by means of die-attach material, the die and the substrate are also mechanically connected by means of the molding compound.

The substrate of such die packages comprises a customary PCB (printed circuit board), preferably of a glass fiber laminate based on synthetic resin. This material has a high strength and a coefficient of thermal expansion that is a multiple of the coefficient of expansion of the die.

On account of the materials firmly joined in this way, of the substrate (synthetic resin) and of the die (silicon), which have very different expansion characteristics, the package shows warping characteristics comparable to a bimetallic effect. In particular, these thermal effects occur under thermal loading, as occurs for example during alternating temperature tests and burn-in (artificial pre-aging). The warping characteristics lead to considerable reliability problems, mainly on account of solder balls becoming detached under the mechanical loading, since a material bond between the die and the substrate is established over the full surface area by means of the balls distributed so as to cover the die area. The solder connections becoming detached under mechanical stress may lead to the total failure of the device. This problem is particularly marked in the case of very large dies, since here the forces on the solder balls are particularly great in critical positions on account of the greater possible warpage.

These reliability problems can be countered in various ways. On the substrate side, the use of suitable stress-absorbing die-attach materials with a minimum thickness is possible. However, there are limits to this stress compensation because of the processability of the material, in particular as from a certain thickness, because of the high water absorbency of the die-attach material and also for reasons of cost.

The encapsulation of the die package can also counteract the warping characteristics to a certain extent, and thereby relieve the electrical contacts. This requires the use of highly flexible molding compounds, which, however, has the disadvantage of a deterioration in the wetting capability, and consequently the reliability of the mechanical connection between the molding compound and the substrate. Furthermore, the complete encapsulation of the die cannot be used everywhere to the required extent, for example for reasons of space.

On the module side, the described reliability problem is countered with varying results by the arrangement of the electrical contacts between the substrate and the module being adapted to the distribution of the failed contacts established under defined thermal or mechanical loading. Such design changes in the bailout of the package are only possible, however, as part of those measures that arise in particular from the electrical contacting requirements, and, in the same way as special solder resist masks or a specific pin design, only lead to a satisfactory result for selected cases.

Furthermore, a specific reduction in the warping characteristics is possible by modifications of the material combinations within the package, but only within the limits allowed by the still existing material pairings. Both the materials that are in contact with each other of the die and the molding compound and those of the molding compound and the substrate, and not least further combinations, for example with the module, nevertheless have significant differences in the coefficients of thermal expansion and consequently cause warping of the package. However, it is not possible for reasons of time alone to perform a continual adaptation of the mounting materials to the die size, since the adaptation of materials always requires a very long lead time.

The adaptation of the material of the PCB with regard to its thermal expansion is known, for example, from German Patent Application 39 20 637, and corresponding U.S. Pat. No. 4,876,120. According to this, the coefficient of expansion of a multilayer printed circuit board or a laminate is set, even direction-dependently if appropriate, by a layer of a liquid-crystal polymer being inserted in the printed circuit board. The negative coefficient of thermal expansion and the high Young's modulus of the liquid-crystal polymer as described in this document allow a laminate and multilayer printed circuit boards produced from it with exactly set coefficients of thermal expansion. However, such printed circuit boards are very cost-intensive on account of the high-value material and, for this reason alone, do not come into consideration as a substrate for die packages.

### SUMMARY OF THE INVENTION

In one aspect, the invention relates to a substrate-based die package with BGA or BGA-like components, substantially comprising a substrate and at least one die. The die is attached on the first side of the substrate by means of die-attach material. The substrate is provided on its second side, lying opposite from the die, with solder balls mounted on contact pads for the electrical connection to printed circuit boards. The die and the substrate are encapsulated on the die side by a mold cap. A number of dies or a number of such die packages may also be arranged on a common substrate strip (matrix strip).

Embodiments of the invention provide an arrangement of a substrate-based die package with BGA or BGA-like components that leads to an improvement in the reliability of the soldered connections of the package to a module and thereby overcomes disadvantages and limitations described and can be produced at low cost and with the existing installations and processes.

For example, in one embodiment the substrate includes three layers, the middle layer being made from a flexible material. Here, the middle layer serves, on the basis of its flexible properties, to a certain extent for the decoupling between the upper layer, which is connected to the die over its surface area by means of die-attach material, and the lower layer, which is connected to the module over its surface area by means of the balls, in that the middle layer can absorb stress moments resulting from the warping characteristics.

If the expected stress loading is very high, the stress-compensating effect can be further increased in particular by a middle layer of adhesive material. What is more, the use of adhesive material for the middle layer is very inexpensive and allows dependable processing, and material can be set very well, in particular with regard to its mechanical and thermal properties. For example, a defined coefficient of thermal expansion or the stability in the heated state can be set by suitable fillers.

### DESCRIPTION OF THE DRAWINGS

The invention is to be explained in more detail below on the basis of an exemplary embodiment. The associated drawing shows the schematic representation of a vertical section through a die package according to the invention, configured as a board-on-chip package. The right half of the die package is shown in the drawing. The left half of the drawing, which is not shown, can be formed in the same way.

The following list of reference symbols can be used in conjunction with the FIGURE:
1 substrate
2 die
3 solder balls
4 adhesive layer
5 central rows of contacts
6 bonding channel
7 wire bridges
   8 redistribution layer
   9 solder resist mask
   10 mold cap
   11 molding compound
   12 upper layer
   13 middle layer
   14 lower layer

### DETAILED DESCRIPTION OF ILLUSTRATIVE EMBODIMENTS

According to the FIGURE, the die package substantially comprises a substrate 1. A die 2, e.g., a semiconductor chip, is mounted on the upper side of the substrate 1. Balls 3 are arranged on the underside of the substrate 1 in a grid-like manner for producing the soldered connection to a module (not shown in any more detail). In the exemplary embodiment represented, the substrate 1 is only slightly larger than the die 2. The die 2 is mounted face down on the substrate 1 by means of an adhesive layer 4 in such a way that its central rows of contacts 5 protrude into a central bonding channel 6 of the substrate 1. The central rows of contacts 5 are connected by means of wire bridges 7 to a redistribution layer 8, which is configured as a structured metallization on the underside of the substrate 1 and electrically contacts the wire bridges 7 with respect to the balls 3. The redistribution layer 8 is covered in the region of the ball arrangement by a solder resist mask 9.

The die 2 is encapsulated by means of a mold cap 10. In the illustrated embodiment, the mold cap 10 covers the entire upper side of the substrate 1. To protect the wire bridges 7, the bonding channel 6 is also filled with a molding compound 11. The underside of the substrate 1 can likewise be covered by the molding compound 11 in the direct vicinity around the bonding channel 6.

The substrate 1 comprises three layers, the upper layer 12 and the lower layer 14, which are made with the glass fiber laminate, and the middle layer 13 of adhesive material. In the preferred embodiment, all three layers 12, 13, 14 have a uniform thickness, which is approximately one third of the thickness generally of single-layered substrates of comparable die packages according to the known prior art.

The flexibility of the middle layer 13 material is to be set to correspond to the expected loading, for example to correspond to the size of die 2. The possibilities for setting the flexibility and the possible minimum thicknesses of the upper and lower layers 12, 14 with regard to processability give rise to an overall thickness of the substrate 1 that is equal to or only slightly greater than the thickness of the previously customary substrates. To increase the decoupling, it is possible for the substrate 1 to be subdivided into more than three layers. For example, a sequence of flexible and rigid layers can be repeated.

It goes without saying that the upper and/or lower layer 12 and/or 14 or a further non-flexible layer can also be made from a multilayered, metallized printed circuit board. For example, multiple routing layers may be required for complex redistribution routing or for other reasons. In other words, the substrate 1 can include embedded conductors.

The stress absorption performed by the flexible layer 13 within the substrate 1 may be performed in addition to and independently of the known measures described in the background for reducing the stress moments acting on the soldered connection. This allows the configuration of the substrate 1 according to embodiments of the invention to be optimized. In particular, the thickness of the die-attach material 4 can be varied so that, for example, moisture introduced into the die package by this material and its water absorption can be reduced. Since both have a considerable influence on the temperature resistance of the package, this measure likewise leads to an improvement in the reliability of the die package.

The subdivision of the substrate into at least three layers 12, 13 and 14 also allows tried-and-tested, low-cost materials to be used. For example, in preferred embodiments glass fiber laminate based on synthetic resin is used exclusively. In other embodiments, this laminate can be used at least for the non-flexible upper and lower layers 12 and 14 together with an adhesive material for the middle layer 13.

As discussed above, the adjacent individual layers can be separated by an electrically effective copper layer that is arranged in between. According to embodiments of the invention, the individual layers can be pressed together without a metallic intermediate layer. In this manner, there is an increased amount of synthetic resin component in the transitional region between the layers. This refinement serves as a flexible middle layer and is consequently capable of absorbing mechanical stress resulting from the warping characteristics of the die package. It proves to be of particular advantage in this respect that the overall thickness of a substrate 1 that includes the three layers 12, 13 and 14 may be approximately of the same thickness as a customary single-layer substrate and nevertheless has the mechanically compensating properties described.

In another embodiment, particles can be introduced into the layer material to produce a uniform layer thickness. Ensuring a uniform layer thickness has the effect of preventing local stress peaks within the flexible layer and consequently of preventing local detachment.

Increased introduction of moisture into the package by the adhesive material of the middle layer 13, influencing the temperature resistance, is unlikely, since, as a difference from the die-attach material, the layer material is not encapsulated in the interior of the package but instead a diffusion can take place via the lateral bounding surfaces of the substrate to the outside.

The decoupling of the upper layer 12 from the lower layer 14 additionally allows at least the upper layer 12, facing the die 2, to be made from a material with mechanical and/or thermal properties which are adapted to the die material. In this way, the mechanical loading of the connection between the die and the substrate is transferred to the middle, stress-dissipating layer or layers of the substrate, where, as already described, a greater range of possibilities for adaptation to the mechanical loading is available by means of setting the material properties and/or the number of layers. For example, the upper layer 12 can be made from silicon.

If, in a way corresponding to a further refinement of the invention, the substrate 1 has a solder resist mask 9, at least on the ball side, additional measures for improving the reliability of the soldered connections can be taken by means of suitable solder resist mask designs. For example, a direction-dependent stiffening or clamping of the pads can be utilized.

For the electrical connection of the die 1 to the balls 3 of the substrate 1, the substrate 1 may be equipped either with electrical vias (not shown) or with a bonding channel 6. If the substrate has vias, there are limits to the flexibility of the middle layer 13, since with very flexible layer material there is the risk of the vias tearing on account of the shearing forces occurring. For this reason, this configuration is used when there are lower expected stresses in the middle layer 13.

In the case where great stresses are expected, it is advantageous for the substrate to include a bonding channel 6 and for the electrical connection of the die 2 to the balls 3 to take place by means of wire bridges 7 through the bonding channel 6. This contacting is also capable of compensating to quite a large extent for lateral displacements of the upper and lower layers 12 and 14 with respect to each other. To protect the wire bridges 7, in this configuration the bonding channel 6 is likewise filled in the known way with a molding compound 11.

1. A substrate-based die package comprising:
a substrate comprising at least an upper layer, a middle layer and a lower layer, wherein the middle layer is disposed between the upper layer and the lower layer and wherein the middle layer is formed from a flexible material;
at least one die, the die being attached on the upper layer of the substrate by means of die-attach material;
solder balls disposed on the lower layer of the substrate, the solder balls being mounted on contact pads for electrical connection to printed circuit boards; and
a mold cap encapsulating the die and a surface of the upper layer of the substrate.

2. The substrate-based die package as claimed in claim 1, wherein the upper layer, the middle layer and the lower layer are made from glass fiber laminate based on synthetic resin.

3. The substrate-based die package as claimed in claim 1, wherein the middle layer comprises an adhesive layer.

4. The substrate-based die package as claimed in claim 3, wherein the middle layer includes particles for setting a uniform layer thickness.

5. The substrate-based die package as claimed in claim 1, wherein at least the upper layer is made from a material with mechanical and/or thermal properties that are adapted to the die material.

6. The substrate-based die package as claimed in claim 1, wherein the upper layer comprises silicon.

7. The substrate-based die package as claimed in claim 1, wherein the substrate further includes a solder resist mask over the lower layer.

8. The substrate-based die package as claimed in claim 1, wherein the substrate includes via holes extending through a portion of the substrate.

9. The substrate-based die package as claimed in claim 1, wherein the die is mounted with an active side face down on the substrate and wherein and the substrate includes a bonding channel, the die being electrically coupled to the solder balls via wire bridges that extend through the bonding channel.

10. A packaged electronic component comprising:
a substrate that includes an upper layer, a lower layer and a middle layer between the upper layer and the lower layer, the middle layer being formed from a first material, the upper layer being formed from a material that is less flexible than the first material and the lower layer being formed from a material that is less flexible than the first material; and
an electronic component adhered over the upper layer of the substrate.

11. The packaged electronic component of claim 10, wherein the electronic component comprises a semiconductor chip.

12. The packaged electronic component of claim 11, further comprising a plurality of solder balls adhered over the lower layer of the substrate.

13. The packaged electronic component of claim 12, wherein at least some of the solder balls lie beneath the semiconductor chip.

14. The packaged electronic component of claim 12, wherein the semiconductor chip includes a center row of bond pads, wherein the electronic component is adhered over the upper layer of the substrate such that the center row of bond pads is aligned with a bonding channel, the packaged electronic component further comprising a plurality of wire bridges extending through the bonding channel and forming an electrical connection between the bond pads and the solder balls.

15. The packaged electronic component of claim 11, wherein the upper layer, the middle layer and the lower layer are each made from glass fiber laminate based on synthetic resin.

16. The packaged electronic component of claim 11, wherein the middle layer comprises an adhesive layer.

17. The packaged electronic component of claim 16, wherein the middle layer includes particles for setting a uniform layer thickness.

18. The packaged electronic component of claim 11, wherein at least the upper layer is made from a material with mechanical and/or thermal properties that are adapted to the die material.

19. The packaged electronic component of claim 10, wherein the substrate further includes a plurality of intermediate layers between the upper layer and the lower layer.

20. The packaged electronic component of claim 19, wherein a plurality of intermediate layers comprises a first intermediate layer and a second intermediate layer, the first intermediate layer being arranged between the upper layer and the second intermediate layer and the second intermediate layer being arranged between the first intermediate layer and the middle layer, the first intermediate layer being more flexible than the second intermediate layer and the upper layer and the second intermediate layer being more rigid than the first intermediate layer and the middle layer.
